(19) United States
(12) Patent Application Publication
(10) Pub. No.: US 2025/0266389 A1
(43) Pub. Date: Aug. 21, 2025

(54) SEMICONDUCTOR MANUFACTURING APPARATUS AND CONTROL METHOD THEREOF

(71) Applicant: Kioxia Corporation, Tokyo (JP)

(72) Inventor: Jun SAGIYA, Mie Mie (JP)

(73) Assignee: Kioxia Corporation, Tokyo (JP)

(21) Appl. No.: 18/820,725

(22) Filed: Aug. 30, 2024

(30) Foreign Application Priority Data
Feb. 15, 2024 (JP) 2024-021273

(51) Int. Cl. H01L 23/00; G01L 1/16; G01L 1/22; G05B 19/4099; H10N 30/30

(52) U.S. Cl. CPC H01L 24/75; G01L 1/16; G01L 1/22; G05B 19/4099; G05B 2219/45031; H01L 2224/75301; H01L 2224/75901; H01L 2224/7592; H10N 30/302

(57) ABSTRACT

An apparatus includes first and second chip bonders. The first chip bonder includes a first holder, a first shaft, a first driver driving the first shaft, and a first pressure sensor detecting a first pressure at which the first driver presses a chip against a bonding target. The second chip bonder includes a second holder, a second shaft, a second driver driving the second shaft, and a second pressure sensor detecting a second pressure at which the second driver presses the chip against the bonding target. A storage stores a first set value of the first pressure and a second set value of the second pressure. A controller controls the first chip bonder to set the first pressure to be the first set value and controls the second chip bonder to set the second pressure to be the second set value.

### CROSS REFERENCE TO RELATED APPLICATIONS

This application is based upon and claims the benefit of priority from the prior Japanese Patent Application No. 2024-021273, filed on Feb. 15, 2024, the entire contents of which are incorporated herein by reference.

### FIELD

The embodiments of the present invention relate to a semiconductor manufacturing apparatus and a control method thereof.

### BACKGROUND

A semiconductor manufacturing apparatus such as a die bonding device may stack a plurality of semiconductor chips on a substrate when bonding a semiconductor chip onto a wiring circuit board. In a case of bonding the semiconductor chips while shifting them in a stepwise manner, an upper semiconductor chip overhangs a lower semiconductor chip. In this case, load is applied to an overhanging portion of the semiconductor chip and there is a risk of causing a crack in the semiconductor chip.

### BRIEF DESCRIPTION OF THE DRAWINGS

FIG. 1 is a diagram illustrating a configuration example of a die bonding device according to a first embodiment;

FIG. 2 is a plan view illustrating a configuration example of a chip bonder according to the first embodiment;

FIG. 3 is a graph illustrating a relation between a pressing force of each chip bonder and a bonding time;

FIG. 4 is a flowchart illustrating an operation example of the die bonding device according to the first embodiment;

FIG. 5 is a flowchart illustrating an example of abnormality determination by a controller; and

FIG. 6 is a diagram illustrating a configuration example of a die bonding device according to a second embodiment.

### DETAILED DESCRIPTION

In general, according to the embodiment, a semiconductor manufacturing apparatus includes a first chip bonder and a second chip bonder. The first chip bonder includes a first holder configured to be capable of holding a first semiconductor chip, a first shaft configured to support the first holder, a first driver configured to drive the first shaft in a first direction that is from the first semiconductor chip toward a bonding target, and a first pressure sensor configured to detect a first pressure at which the first driver presses the first semiconductor chip against the bonding target via the first shaft. The second chip bonder includes a second holder configured to be capable of holding the first semiconductor chip, a second shaft configured to support the second holder, a second driver configured to drive the second shaft in the first direction, and a second pressure sensor configured to detect a second pressure at which the second driver presses the first semiconductor chip against the bonding target via the second shaft. A storage is configured to store therein a first set value of the first pressure and a second set value of the second pressure. A controller is configured to control the first chip bonder to set the first pressure to be the first set value and control the second chip bonder to set the second pressure to be the second set value. Hereinafter, apparatuses of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

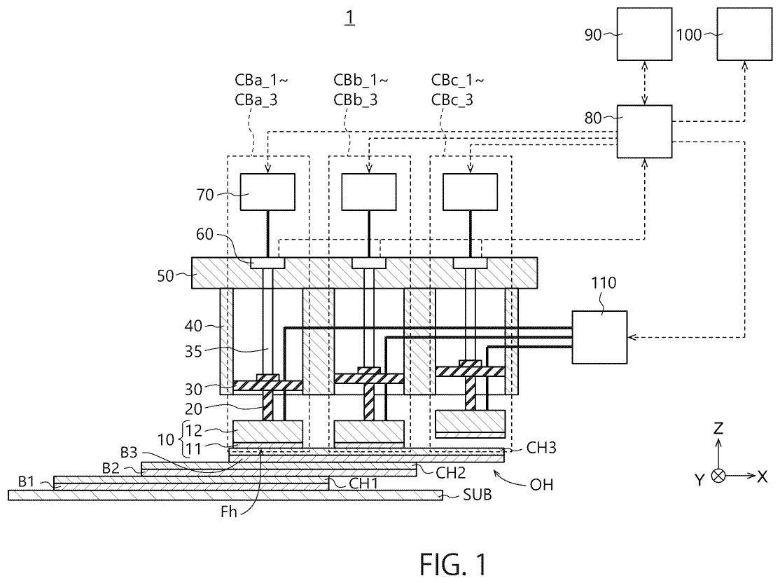

FIG. 1 is a diagram illustrating a configuration example of a die bonding device according to a first embodiment. A die bonding device 1 stacks semiconductor chips CH1 to CH3 on a substrate SUB while shifting them in the X direction, for example. Accordingly, the semiconductor chips CH1 to CH3 are stacked on the substrate SUB in a stepwise manner. The semiconductor chips CH1 to CH3 and the substrate SUB are bonded to each other with adhesives B1 to B3.

The die bonding device 1 includes chip bonders CBa_1 to CBa_3, CBb_1 to CBb_3, and CBc_1 to CBc_3, a controller 80, a storage 90, a display 100, and a pump 110.

The chip bonders CBa_1 to CBa_3, CBb_1 to CBb_3, and CBc_1 to CBc_3 all have the same configuration. Therefore, the configuration of the chip bonder CBa_1 is described here, and descriptions of the configurations of the chip bonders CBa_2, CBa_3, CBb_1 to CBb_3, and CBc_1 to CBc_3 are omitted.

The chip bonder CBa_1 includes a bonding tool 10, a shaft 20, a head shaft 30, a pressurizing pipe 35, a cylinder sidewall 40, a cylinder head 50, a pressure sensor 60, and a pump 70.

The bonding tool 10 as a holder is configured to be able to hold the semiconductor chip CH1, CH2, or CH3 by absorbing it. For example, the bonding tool 10 includes a tool body 12 having a holding surface Fh that holds the semiconductor chip CH1, CH2, or CH3 and a flexible absorbing cover 11 covering the holding surface Fh of the tool body 12. A rigid material, such as metal and ceramic, is used for the tool body 12. A resin material, such as flexible rubber and silicone, is used for the absorbing cover 11. The bonding tool 10 may be configured by ceramic as a whole.

The absorbing cover 11 and the tool body 12 have a hole (not illustrated) for absorbing the semiconductor chip CH1, CH2, or CH3. The pump 110 sucks the air through the hole to cause the semiconductor chip CH1, CH2, or CH3 to be absorbed to the absorbing cover 11 by negative pressure. That is, the bonding tool 10 absorbs the semiconductor chip CH1, CH2, or CH3 with a vacuum chuck. The bonding tool 10 may absorb the semiconductor chip CH1, CH2, or CH3 with an electromagnetic chuck.

The shaft 20 is connected between the head shaft 30 and the tool body 12 and supports the bonding tool 10. The shaft 20 is provided in the central portion of the tool body 12 in plan view when viewed from the Z direction and presses the bonding tool 10 to the −Z direction substantially evenly.

The head shaft 30 is connected to one end of the shaft 20 and slides on the inner surface of the cylinder sidewall 40. Since the shaft 20 presses the bonding tool 10 substantially evenly, the head shaft 30 can move in the inner space of the cylinder sidewall 40 in the Z direction while being kept substantially parallel to the surface of the substrate SUB.

The pressurizing pipe 35 is pipe-connected between the head shaft 30 and the pump 70. The pump 70 sends gas into the pressurizing pipe 35 to press the head shaft 30 and the shaft 20 to the −Z direction at the atmospheric pressure. Accordingly, the bonding tool 10 can press the semiconductor chip CH1, CH2, or CH3 to the −Z direction and stack it on the substrate SUB.

The cylinder head 50 closes the inner space of the cylinder sidewall 40. A metal material, for example, tungsten is used for the shaft 20, the head shaft 30, the pressurizing pipe 35, the cylinder sidewall 40, and the cylinder head 50.

The pressure sensor 60 is provided in the pressurizing pipe 35 and detects the pressure (hereinafter, also “pressing force”) at which the bonding tool 10 presses the semiconductor chip CH1, CH2, or CH3 against the substrate SUB. For example, a piezoelectric sensor using a piezoelectric element or a resistive sensor using a strain gauge is used as the pressure sensor 60.

The pump 70 as a driver is an air pump that drives the shaft 20 at the pressure of gas via the pressurizing pipe 35. The pump 70 drives the shaft 20 to the −Z direction that is from the semiconductor chip CH1, CH2, or CH3 toward the substrate SUB or the semiconductor chip CH1 or CH2 below the semiconductor chip CH1, CH2, or CH3 under control of the controller 80. At this time, the bonding tool 10 presses the semiconductor chip CH1, CH2, or CH3 against the substrate SUB or the semiconductor chip CH1 to CH2 at a predetermined pressure. Accordingly, the semiconductor chips CH1 to CH3 are stacked and bonded on the substrate SUB.

The controller 80 receives the pressure detected by the pressure sensor 60 and controls the pumps 70 and 110. The storage 90 stores therein a set value of the pressing force (hereinafter, also “set pressure value”) of the bonding tool 10 in advance. The controller 80 acquires the set pressure value from the storage 90 and controls the pump 70 to set the pressing force of the bonding tool 10 to be the set pressure value.

The storage 90 may have a threshold slightly lower than the set pressure value. In this case, the controller 80 can automatically determine that an abnormality has occurred when the pressing force drops below the threshold during pressing of any of the semiconductor chips CH1 to CH3.

The display 100 displays the set pressure value and a change over time in the pressing force detected by the pressure sensor 60. Such display enables an operator to determine that an abnormality has occurred when the pressing force temporarily decreases.

As described above, the controller 80 may automatically determine an abnormality or the operator may determine an abnormality by referring to the change over time in the pressing force on the display 100.

The abnormality means, for example, a damage of any of the semiconductor chips CH1 to CH3 during pressing of the semiconductor chip CH1, CH2, or CH3. In more detail, the semiconductor chip CH2 is stacked to be shifted with respect to the semiconductor chip CH1 in the X direction. The semiconductor chip CH3 is stacked to be shifted with respect to the semiconductor chips CH1 and CH2 in the X direction. In this case, a space is formed between the semiconductor chips CH2 and CH3 and the substrate SUB. Therefore, when the chip bonders CBa_1 to CBc_3 press the semiconductor chip CH2 or CH3 at an excessive pressure to the −Z direction, an overhanging portion OH of the semiconductor chip CH2 or CH3 may be bent to the −Z direction to crack. The controller 80 or the operator determines the occurrence of such an abnormality.

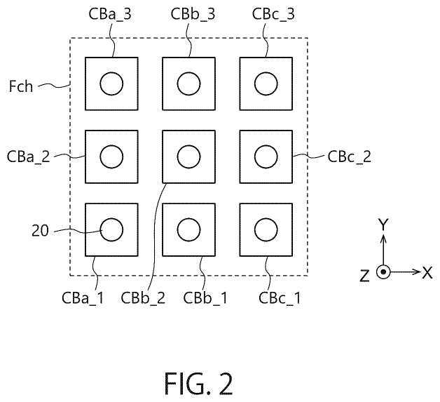

FIG. 2 is a plan view illustrating a configuration example of a chip bonder according to the first embodiment. FIG. 2 is a plan view of the chip bonders CBa_1 to CBa_3, CBb_1 to CBb_3, and CBc_1 to CBc_3 (hereinafter, collectively “CBa_1 to CBc_3”) in FIG. 1 when viewed from the Z direction.

The die bonding device 1 according to the present embodiment includes the nine chip bonders CBa_1 to CBc_3. The chip bonders CBa_1 to CBc_3 absorb a chip surface Fch of one semiconductor chip (any of CH1 to CH3) at a time and bond it onto the substrate SUB or the remaining one of the semiconductor chips CH1 and CH2. The chip surface Fch is a surface of the semiconductor chip CH1, CH2, or CH3 held by the holding surface Fh of the bonding tool 10.

The chip bonders CBa_1 to CBc_3 all have the same configuration as described above.

The chip bonders CBa_1 to CBc_3 are arranged substantially evenly with respect to the chip surface Fch of the semiconductor chip CH1, CH2, or CH3. Therefore, the chip bonders CBa_1 to CBc_3 can press the semiconductor chip CH1, CH2, or CH3 against the substrate SUB or the remaining one of the semiconductor chips CH1 and CH2 with substantially equal pressing forces substantially evenly. The shafts 20 are respectively connected to the centers of the chip bonders CBa_1 to CBc_3 to press those centers to the −Z direction substantially evenly.

Meanwhile, the chip bonders CBa_1 to CBc_3 according to the present embodiment are divided into a plurality of parts (e.g., nine parts) that can press the semiconductor chip CH1, CH2, or CH3 independently with different pressing forces. In this case, the set pressure value and the threshold are set for each of the chip bonders CBa_1 to CBc_3 and are stored in the storage 90. The controller 80 controls the chip bonders CBa_1 to CBc_3 to set the pressing force of the bonding tool 10 of each of the chip bonders CBa_1 to CBc_3 to be the corresponding set pressure value.

For example, in the overhanging portion OH of the semiconductor chip CH2 or CH3 in FIG. 1, it is desirable that the chip bonders CBb_1 to CBb_3 press the semiconductor chips CH1 to CH3 with lower pressing forces than those of the chip bonders CBa_1 to CBa_3. It is desirable that the chip bonders CBc_1 to CBc_3 press the semiconductor chips CH1 to CH3 with lower pressing forces than those of the chip bonders CBb_1 to CBb_3. Therefore, in a case of bonding the semiconductor chip CH3 onto the semiconductor chip CH2, for example, the set pressure values and the thresholds for the chip bonders CBb_1 to CBb_3 are set to be lower than those for the chip bonders CBa_1 to CBa_3. The set pressure values and the thresholds for the chip bonders CBc_1 to CBc_3 are set to be lower than those for the chip bonders CBb_1 to CBb_3. Accordingly, a crack in the semiconductor chip CH2 or CH3 can be prevented.

If the chip bonders CBa_1 to CBc_3 are configured as a single chip bonder, the single chip bonder presses the entire chip surface Fch of a semiconductor chip at a uniform pressing force. In this case, it is highly likely that the semiconductor chip cracks in the overhanging portion described above. Alternatively, in a case where the pressing force is set to be low so as to prevent a crack in the semiconductor chip, the chip bonder cannot bond the semiconductor chip sufficiently.

In contrast thereto, in the present embodiment, the chip bonders are divided into a plurality of parts (e.g., nine parts), and the plural chip bonders CBa_1 to CBc_3 bond the semiconductor chips CH1 to CH3 one by one on the substrate SUB or the remaining one of the semiconductor chips CH1 and CH2. At this time, the chip bonders CBa_1 to CBc_3 press the semiconductor chip CH1, CH2, or CH3 independently with the set pressure values respectively corresponding thereto, as described above. Accordingly, the chip bonders CBa_1 to CBc_3 can press the semiconductor chip CH1, CH2, or CH3 with pressing forces different from each other. That is, the chip bonders CBa_1 to CBc_3 can press the chip surface Fch of the semiconductor chip CH1, CH2, or CH3 with pressing forces partially different.

For example, when the semiconductor chip CH1 is bonded to the substrate SUB, the chip bonders CBa_1 to CBc_3 press the semiconductor chip CH1 against the substrate SUB with substantially equal pressing forces substantially evenly. When the semiconductor chip CH2 is bonded to the semiconductor chip CH1, the chip bonders CBa_1 to CBa_3 and CBb_1 to CBb_3 press the semiconductor chip CH2 against the semiconductor chip CH1 with substantially equal pressing forces, and the chip bonders CBc_1 to CBc_3 press the semiconductor chip CH2 with pressing forces lower than those of the chip bonders CBa_1 to CBa_3 and CBb_1 to CBb_3. When the semiconductor chip CH3 is bonded to the semiconductor chip CH2, the chip bonders CBa_1 to CBa_3 press the semiconductor chip CH3 against the semiconductor chip CH2 with substantially equal pressing forces, and the chip bonders CBb_1 to CBb_3 and CBc_1 to CBc_3 press the semiconductor chip CH3 with pressing forces lower than those of the chip bonders CBa_1 to CBa_3. Accordingly, the chip bonders CBa_1 to CBc_3 can sufficiently bond the semiconductor chips CH1 to CH3 while preventing a crack in the semiconductor chips CH1 to CH3.

Nine chip bonders are provided in the above embodiment. However, the number of the chip bonders is not limited thereto. For example, in a case where n chip bonders (n is a positive integer) are provided, the n-th chip bonder (not illustrated) has the configuration identical to that of the chip bonder CBa_1 and includes the bonding tool 10, the shaft 20, the head shaft 30, the pressurizing pipe 35, the cylinder sidewall 40, the cylinder head 50, the pressure sensor 60, and the pump 70 illustrated in FIG. 1.

The first to n-th chip bonders absorb the chip surface Fch of one of the semiconductor chips CH1 to CH3 at a time and bond it on the substrate SUB or the remaining one of the semiconductor chips CH1 and CH2. The first to n-th chip bonders are arranged substantially evenly with respect to the chip surface Fch of the semiconductor chip CH1, CH2, or CH3. The first to n-th chip bonders can press the semiconductor chip CH1, CH2, or CH3 with different pressing forces independently of each other. The set pressure value and the threshold are set for each of the first to n-th chip bonders and are stored in the storage 90. Accordingly, the first to n-th chip bonders press the semiconductor chip CH1, CH2, or CH3 with pressing forces based on the respective set pressure values independently of each other. Therefore, the first to n-th chip bonders can sufficiently bond the semiconductor chips CH1 to CH3 while preventing a crack in the semiconductor chips CH1 to CH3. As described above, the effects of the present embodiment can be obtained also in a case where chip bonders are divided into n parts.

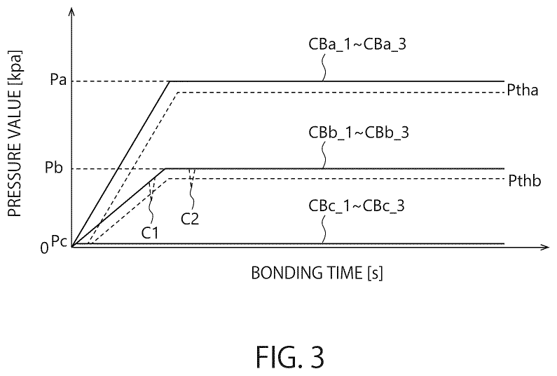

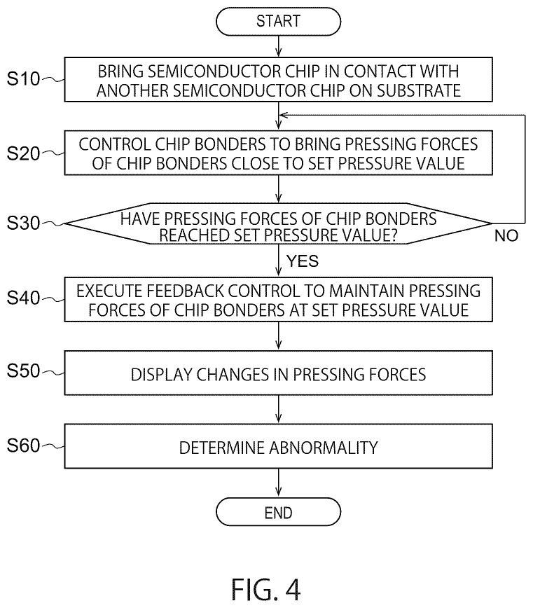

FIG. 3 is a graph illustrating a relation between a pressing force of each chip bonder and a bonding time. An operator can refer to this graph on the display 100. FIG. 4 is a flowchart illustrating an operation example of the die bonding device according to the first embodiment. Abnormality detection by the die bonding device 1 and operations thereof are described with reference to FIGS. 3 and 4.

As illustrated in FIG. 3, in a case of pressing the semiconductor chips CH1 to CH3, the set pressure values of the chip bonders CBa_1 to CBa_3 are set to Pa that is relatively high. For example, in a case of pressing the semiconductor chip CH3, the set pressure values of the chip bonders CBb_1 to CBb_3 are set to Pb lower than Pa. The set pressure values of the chip bonders CBc_1 to CBc_3 are set to Pc lower than Pa and Pb. The set pressure value Pc is approximately 0. The set pressure values Pa, Pb, and Pc are set based on pressing forces measured in advance by using a test semiconductor chip (not illustrated) having the same configuration as the semiconductor chips CH1 to CH3. The set pressure values Pa, Pb, and Pc set in this manner are stored in the storage 90 in advance.

As illustrated in FIG. 4, in a bonding process, the chip bonders CBa_1 to CBb_3 absorb the semiconductor chip CH3 and bring it in contact with the semiconductor chip CH2 on the semiconductor chip CH1 stacked on the substrate SUB (S10). At Step S10, the chip bonders CBa_1 to CBc_3 may absorb the semiconductor chip CH3 and bring it in contact with the semiconductor chip CH2.

Next, the controller 80 controls the chip bonders CBa_1 to CBa_3 to bring the pressing forces of the chip bonders CBa_1 to CBa_3 close to the set pressure value Pa (S20 and No at S30). The controller 80 controls the chip bonders CBb_1 to CBb_3 to bring the pressing forces of the chip bonders CBb_1 to CBb_3 close to the set pressure value Pb. The controller 80 controls the chip bonders CBc_1 to CBc_3 to bring the pressing forces of the chip bonders CBc_1 to CBc_3 close to the set pressure value Pc. In a case where the set pressure value Pc is 0, the chip bonders CBc_1 to CBc_3 do not press the semiconductor chip CH3.

When the pressing forces of the chip bonders CBa_1 to CBa_3 reach the set pressure value Pa (YES at S30), the controller 80 executes feedback control to maintain the pressing forces of the chip bonders CBa_1 to CBa_3 at the set pressure value Pa (S40). When the pressing forces of the chip bonders CBb_1 to CBb_3 reach the set pressure value Pb, the controller 80 executes feedback control to maintain the pressing forces of the chip bonders CBb_1 to CBb_3 at the set pressure value Pb. When the pressing forces of the chip bonders CBc_1 to CBc_3 reach the set pressure value Pc, the controller 80 executes feedback control to maintain the pressing forces of the chip bonders CBc_1 to CBc_3 at the set pressure value Pc. In a case where the set pressure value Pc is 0, the chip bonders CBc_1 to CBc_3 maintain the pressure values at 0.

Here, it is assumed that the overhanging portion OH of the semiconductor chip CH2 or CH3 cracks because of the pressing forces of the chip bonders CBb_1 to CBb_3. In this case, it is considered that the pressing forces of the chip bonders CBb_1 to CBb_3 decrease transitionally. For example, a crack pressure C1 in FIG. 3 is a transitional pressure decrease that has occurred while the pressing forces of the chip bonders CBb_1 to CBb_3 are increased. A crack pressure C2 is a transitional pressure change, that is, a pressure decrease that has occurred after the pressing forces of the chip bonders CBb_1 to CBb_3 have reached the set pressure value Pb. By detection of the pressing forces of the chip bonders CBa_1 to CBc_3 by the pressure sensors 60, the display 100 can display changes over time in the pressing forces illustrated in FIG. 3 (S50). The display 100 displays the changes over time in the pressing forces of the chip bonders CBa_1 to CBc_3 separately.

An operator refers to the changes over time in the pressing forces on the display 100 and, when the crack pressure C1 or C2 has been generated, determines that a crack has occurred in the semiconductor chip CH2 or CH3 (S60).

According to the present embodiment, chip bonders are divided into a plurality of parts (e.g., nine parts). Therefore, when the semiconductor chip CH2 or CH3 has cracked, it is possible to easily determine that crack by detecting changes in the pressing forces of the chip bonders CBb_1 to CBb_3 that are a part of the plural chip bonders CBa_1 to CBc_3. For example, when the semiconductor chip CH2 or CH3 has cracked, the pressing forces of the chip bonders CBb_1 to CBb_3 appear as illustrated with the crack pressure C1 or C2 in FIG. 3. Accordingly, the operator can refer to the changes over time in the pressing forces on the display 100 and, when the crack pressure C1 or C2 has been generated, can easily determine that an abnormality such as a crack has occurred in the semiconductor chip CH2 or CH3.

Further, according to the present embodiment, by setting thresholds Ptha and Pthb, the controller 80 may automatically determine an abnormality. For example, as illustrated in FIG. 3, it is assumed that the threshold Ptha is lower than the set pressure value Pa by a predetermined value. It is also assumed that the threshold Pthb is lower than the set pressure value Pb by a predetermined value. As for time periods in which the pressing forces are increased from the start of bonding to reach the set pressure values Pa and Pb, it suffices that the thresholds Ptha and Pthb are each set to a value lower than a pressing force measured in advance by using a test semiconductor chip by a predetermined value. The thresholds Ptha and Pthb are stored in the storage 90 in advance. Since the set pressure value Pc is 0, a threshold for the chip bonders CBc_1 to CBc_3 is not set here.

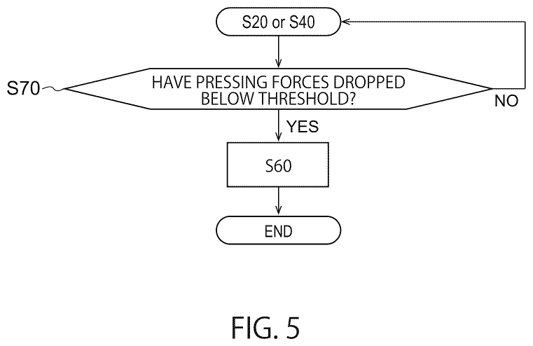

FIG. 5 is a flowchart illustrating an example of abnormality determination by a controller. The basic bonding operation may be the same as the operation illustrated in FIG. 4.

While the semiconductor chip CH1, CH2, or CH3 is pressed (S20 or S40), the controller 80 determines an abnormality when the pressing forces of the chip bonders CBa_1 to CBa_3 drop below the threshold Ptha (YES at S70) (S60). Alternatively, while the semiconductor chip CH1, CH2, or CH3 is pressed, the controller 80 determines an abnormality when the pressing forces of the chip bonders CBb_1 to CBb_3 drop below the threshold Pthb.

For example, in a case where the pressing forces have transitionally decreased and the crack pressure C1 has been generated during pressurization by the chip bonders CBb_1 to CBb_3 (S20) as illustrated in FIG. 3, the controller 80 determines that an abnormality has occurred because the crack pressure C1 is lower than the threshold Pthb (S60). Also in a case where the crack pressure C2 has been generated during feedback control of the pressing forces of the chip bonders CBb_1 to CBb_3 (S40), the controller 80 determines that an abnormality has occurred because the crack pressure C2 is lower than the threshold Pthb (S60). As described above, the controller 80 can automatically determine an abnormality based on a change over time in the pressing force.

When the controller 80 has determined the occurrence of an abnormality, the controller 80 causes the display 100 to display an alert that notifies the occurrence of the abnormality.

Step S70 may be performed at Step S50 in FIG. 3.

As described above, according to the present embodiment, although an operator may determine the occurrence of the abnormality by referring to the display 100, the controller 80 may automatically determine an abnormality based on the threshold Ptha or Pthb.

### Second Embodiment

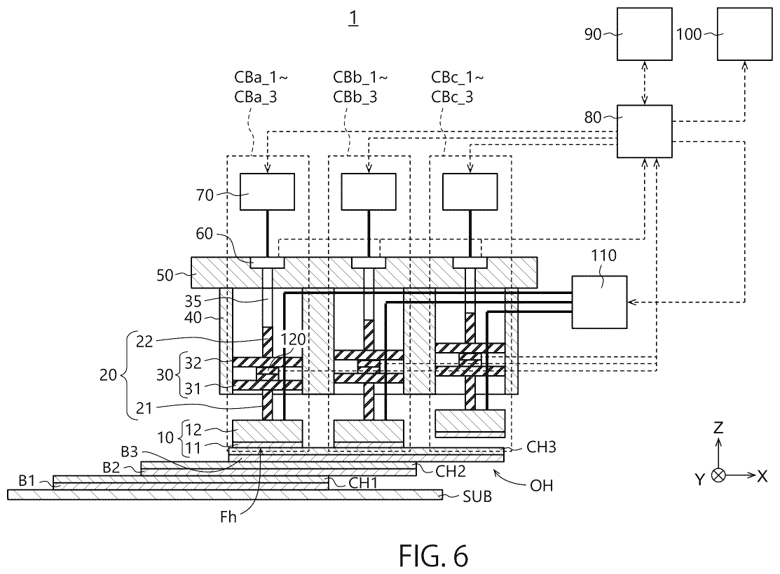

FIG. 6 is a diagram illustrating a configuration example of a die bonding device according to a second embodiment. Also in this embodiment, the configuration of the chip bonder CBa_1 is described, and the descriptions of the configurations of the chip bonders CBa_2, CBa_3, CBb_1 to CBb_3, and CBc_1 to CBc_3 are omitted.

In the chip bonder CBa_1 according to the second embodiment, the shaft 20 includes a shaft portion 21 connected to the bonding tool 10 and a shaft portion 22 provided on the pump 70 side. The head shaft 30 includes a head portion 31 provided on the shaft portion 21 side and a head portion 32 provided on the shaft portion 22 side. Further, the chip bonder CBa_1 includes a pressure sensor 120 provided between the head portion 31 and the head portion 32, that is, between the shaft portion 21 and the shaft portion 22.

The shaft portion 21 is connected between the bonding tool 10 and the head portion 31. The shaft portion 22 is connected between the head portion 32 and the pressurizing pipe 35. The shaft portions 21 and 22 are provided in the central portion of the tool body 12 in plan view when viewed from the Z direction and are arranged to press the bonding tool 10 to the −Z direction substantially evenly. The pressurizing pipe 35 pressurizes the shaft portion 22 to press the semiconductor chip CH1, CH2, or CH3 via the head portions 31 and 32 and the shaft portion 21.

The head portion 31 is connected to the upper end of the shaft portion 21. The head portion 32 is connected to the lower end of the shaft portion 22. The head portion 31 and the head portion 32 are opposed to each other. The pressure sensor 120 is provided between the head portion 31 and the head portion 32, that is, between the shaft portion 21 and the shaft portion 22 at a position extending the center axes of the shaft portion 21 and the shaft portion 22.

The pressure sensor 120 is provided between the head portion 31 and the head portion 32 and detects the pressure between the head portion 31 and the head portion 32. Accordingly, the pressure sensor 120 can detect the pressing force with which the pump 70 presses the semiconductor chip CH1, CH2, or CH3 via the shaft 20 and the head shaft 30. For example, a piezoelectric sensor using a piezoelectric element or a resistive sensor using a strain gauge is used as the pressure sensor 120.

The rest of the configurations of the chip bonder CBa_1 according to the second embodiment may be identical to that of the chip bonder CBa_1 according to the first embodiment.

The rest of the configurations of the die bonding device 1 according to the second embodiment may be identical to that of the first embodiment.

In the second embodiment, the controller 80 receives the pressing forces detected by not only the pressure sensors 60 but also the pressure sensors 120. The controller 80 may cause the display 100 to display the pressing forces from the pressure sensors 120 in place of or together with the pressing forces from the pressure sensors 60. Further, the controller 80 may automatically determine the occurrence of an abnormality by using the pressing forces from the pressure sensors 120 in place of or together with the pressing forces from the pressure sensors 60.

In a case of using both the pressing forces respectively detected by the pressure sensors 60 and 120, the controller 80 may use an average value of the pressing forces from the pressure sensors 60 and 120. Accordingly, the reliability of abnormality determination is improved.

In a case of using the pressure sensor 120 instead of the pressure sensor 60, the pressure sensor 60 may be omitted.

Operations of the die bonding device 1 according to the second embodiment are different from those in the first embodiment in that the pressing forces from the pressure sensors 120 are used for determining an abnormality. However, the rest of the operations in the second embodiment may be identical to that in the first embodiment. Accordingly, the second embodiment can obtain the same effects as those of the first embodiment.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

1. A semiconductor manufacturing apparatus comprising:
a first chip bonder including a first holder configured to be capable of holding a first semiconductor chip, a first shaft configured to support the first holder, a first driver configured to drive the first shaft in a first direction that is from the first semiconductor chip toward a bonding target, and a first pressure sensor configured to detect a first pressure at which the first driver presses the first semiconductor chip against the bonding target via the first shaft;
a second chip bonder including a second holder configured to be capable of holding the first semiconductor chip, a second shaft configured to support the second holder, a second driver configured to drive the second shaft in the first direction, and a second pressure sensor configured to detect a second pressure at which the second driver presses the first semiconductor chip against the bonding target via the second shaft;
a storage configured to store therein a first set value of the first pressure and a second set value of the second pressure; and
a controller configured to control the first chip bonder to set the first pressure to be the first set value and control the second chip bonder to set the second pressure to be the second set value.

2. The apparatus of claim 1, wherein the first and second drivers are pumps configured to drive the first and second shafts at gas pressures, respectively.

3. The apparatus of claim 1, wherein
the first shaft includes a first portion connected to the first holder and a second portion provided on a side of the first driver,
the second shaft includes a third portion connected to the second holder and a fourth portion provided on a side of the second driver,
the first pressure sensor is provided between the first portion and the second portion, and
the second pressure sensor is provided between the third portion and the fourth portion.

4. The apparatus of claim 1, wherein
the first shaft includes a first portion connected to the first holder and a second portion provided on a side of the first driver,
the second shaft includes a third portion connected to the second holder and a fourth portion provided on a side of the second driver,
the first chip bonder further includes a third pressure sensor provided between the first portion and the second portion and configured to detect a third pressure between the first portion and the second portion, and
the second chip bonder further includes a fourth pressure sensor provided between the third portion and the fourth portion and configured to detect a fourth pressure between the third portion and the fourth portion.

5. The apparatus of claim 1, wherein the first and second pressure sensors are piezoelectric sensors each using a piezoelectric element or resistive sensors each using a strain gauge.

6. The apparatus of claim 4, wherein
the third pressure sensor is arranged between the first portion and the second portion at a crossing position with each of center axes of the first portion and the second portion, and
the fourth pressure sensor is arranged between the third portion and the fourth portion at a crossing position with each of center axes of the third portion and the fourth portion.

7. The apparatus of claim 4, wherein the third and fourth pressure sensors are piezoelectric sensors each using a piezoelectric element or resistive sensors each using a strain gauge.

8. The apparatus of claim 1, further comprising a pump configured to cause the first semiconductor chip to be absorbed to the first holder and the second holder.

9. The apparatus of claim 1, wherein the first holder and the second holder are configured by rubber or ceramic.

10. The apparatus of claim 1, further comprising an n-th (n is an integer greater than or equal to 3) chip bonder that includes an n-th holder configured to be capable of holding the first semiconductor chip, an n-th shaft configured to support the n-th holder, an n-th driver configured to drive the n-th shaft in the first direction, and an n-th pressure sensor configured to detect an n-th pressure at which the n-th driver presses the first semiconductor chip against the bonding target via the n-th shaft, wherein
the storage stores therein the first set value to an n-th set value of the first pressure to the n-th pressure, and
the controller controls the first to n-th chip bonders to set the first to n-th pressures to be the first to n-th set values, respectively.

11. The apparatus of claim 10, wherein the first to n-th chip bonders are arranged substantially evenly with respect to a surface of the first semiconductor chip.

12. The apparatus of claim 1, wherein the controller determines an abnormality based on changes over time in the first and second pressures.

13. The apparatus of claim 1, wherein
the storage further stores therein a first threshold related to the first pressure and a second threshold related to the second pressure, and
the controller determines an abnormality when the first pressure drops below the first threshold or the second pressure drops below the second threshold during pressing of the first semiconductor chip.

14. The apparatus of claim 1, wherein the first and second set values are set based on the first and second pressures measured for another semiconductor chip.

15. A control method of a semiconductor manufacturing apparatus including: a first chip bonder that includes a first holder configured to be capable of holding a first semiconductor chip, a first shaft configured to support the first holder, and a first pressure sensor configured to detect a first pressure at which the first semiconductor chip is pressed against a bonding target via the first shaft; a second chip bonder that includes a second holder configured to be capable of holding the first semiconductor chip, a second shaft configured to support the second holder, and a second pressure sensor configured to detect a second pressure at which the first semiconductor chip is pressed against the bonding target via the second shaft; and a controller configured to control the first and second pressures, the method comprising
controlling the first chip bonder to set the first pressure to be a first set value of the first pressure and controlling the second chip bonder to set the second pressure to be a second set value of the second pressure.

16. The method of claim 15, wherein the first and second shafts press the first semiconductor chip against the bonding target at gas pressures, respectively.

17. The method of claim 15, further comprising determining an abnormality based on changes over time in the first and second pressures during pressing of the first semiconductor chip against the bonding target.

18. The method of claim 17, wherein the abnormality is determined based on transitional pressure decreases in the first and second pressures during pressurizing control until the first and second pressures reach the first and second set values, respectively, and during control of maintaining pressure values of the first and second pressures that have reached the first and second set values, respectively.

19. The method of claim 17, wherein the controller determines the abnormality when the first pressure drops below a first threshold or the second pressure drops below a second threshold during pressing of the first semiconductor chip against the bonding target.

20. The method of claim 15, wherein the first and second set values are set based on the first and second pressures measured for another semiconductor chip.
